(19) United States
(12) Patent Application Publication
(10) Pub. No.: US 2025/0268093 A1
(43) Pub. Date: Aug. 21, 2025

(54) DISPLAY DEVICE

(71) Applicant: LG DISPLAY CO., LTD., Seoul (KR)

(72) Inventors: Kelly Sooyeun SONG, Paju-si (KR); SoJung PARK, Paju-si (KR)

(73) Assignee: LG DISPLAY CO., LTD., Seoul (KR)

(21) Appl. No.: 19/030,313

(22) Filed: Jan. 17, 2025

(30) Foreign Application Priority Data
Feb. 16, 2024 (KR) 10-2024-0022266

(51) Int. Cl. H10K 77/10; G02F 1/1333; H10K 102/00

(52) U.S. Cl. CPC H10K 77/111; G02F 1/133305; H10K 2102/311

(57) ABSTRACT

A display device can include a display panel including a plurality of subpixels, a substrate having a first surface facing the display panel and a second surface facing away from the first surface, a plurality of groove patterns on at least one of the first surface of the substrate or the second surface of the substrate, each of the plurality of groove patterns including a first part having a width equal to or smaller than a reference width and a second part having a width equal to or larger than the reference width, the second part having an outwardly convex shape, and an adhesive member disposed on the substrate to fill the plurality of groove patterns.

### CROSS-REFERENCE TO RELATED APPLICATION

This application claims priority to Korean Patent Application No. 10-2024-0022266 filed in the Republic of Korea, on Feb. 16, 2024, the entirety of which is hereby incorporated by reference into the present application for all purposes as if fully set forth herein.

### BACKGROUND

### Field

Embodiments of the present disclosure relate to a display device.

### Description of Related Art

As technology advances, a display device which displays an image, etc. is becoming increasingly lighter and thinner. In addition, in order to be applicable to various applications, the display device should be manufactured so that it can be easily curved or bent when an external force is applied.

However, stress occurs in a course in which the display device is curved or bent by an external force. Specifically, differences in stress and physical properties occur between various layers which constitute the display device, at a location where the display device is curved or bent or in the bending area of the display device.

In this way, when differences in stress and physical properties occur between the various layers which constitute the display device, a delamination phenomenon can occur in which various layers constituting the inside of the display device are separated from each other, or distortion can occur in the bending area, resulting in a problem that the performance of the display device degrades.

Thus, a need exists for a display device having a configuration that can facilitate bending while preventing damage and delamination within the display device.

### SUMMARY OF THE DISCLOSURE

Embodiments of the present disclosure are directed to providing a display device capable of preventing a delamination phenomenon inside the display device.

Embodiments of the present disclosure are directed to providing a display device capable of preventing distortion in the bending area of the display device.

According to embodiments of the present disclosure, a display device can include a display panel, a substrate having a first surface which faces one surface of the display panel and a second surface which faces away from the first surface, and including a plurality of groove patterns which are located on at least one of the first surface or the second surface, each of the plurality of groove patterns including a first part which has a width equal to or smaller than a reference width and a second part which has a width equal to or larger than the reference width and which has an outwardly convex shape, and an adhesive member disposed on the substrate to fill the groove patterns.

According to embodiments of the present disclosure, a display device can include a display panel, a substrate having a first surface which faces one surface of the display panel and a second surface which faces away from the first surface, and including a plurality of groove patterns which are located on at least one of the first surface or the second surface, each of the plurality of groove patterns including a first part which has a surface at least partially flat toward an outside and a second part which has an outwardly convex shape, and an adhesive member disposed on the substrate to fill the groove patterns.

According to embodiments of the present disclosure, a flexible display device can include: a display panel including a plurality of subpixels, a substrate having a bending area and a non-bending area, an adhesive member disposed between the display panel and the substrate, and a plurality of groove patterns in the bending area of the substrate, each grove pattern among the plurality of groove patterns including a first part corresponding to a bottom of the grove pattern and a second part corresponding to an opening of the grove pattern, wherein a side of the first part has a first slope, and a side of the second part has a second slope different than the first slope, and wherein portions of the adhesive member extend at least partially into the plurality of groove patterns.

According to the embodiments of the present disclosure, it is possible to provide a display device capable of preventing a delamination phenomenon inside the display device.

According to the embodiments of the present disclosure, it is possible to provide a display device capable of preventing distortion in the bending area of the display device.

According to the embodiments of the present disclosure, by preventing a peeling phenomenon inside the display device and preventing distortion in the bending area of the display device, degradation in the performance of the display device can be prevented and the lifespan of the display device can be increased, whereby it is possible to provide a display device capable of low power consumption.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, which are briefly described below.

FIG. 1 is a view showing an example of the cross-sectional structure of a display device according to an embodiment of the present disclosure.

FIG. 2 is an enlarged view of a part A of FIG. 1, showing a structure in which the display device is bent according to an embodiment of the present disclosure.

FIG. 3A is a view showing an example of the cross-sectional structure of a comparative example display device and a partially enlarged structure thereof.

FIG. 3B is a view showing a structure in which the display device having the cross-sectional structure of FIG. 3A is bent.

FIG. 4 is a view illustrating an example of a part of the cross-sectional structure of a display device according to embodiments of the present disclosure.

FIG. 5 is a view showing an example in which the cross-sectional structure of FIG. 4 is deformed according to an embodiment of the present disclosure.

FIG. 6 is a view showing a structure in which the display device including the cross-sectional structure of FIG. 4 is bent according to an embodiment of the present disclosure.

FIGS. 7A, 7B and 7C, and FIGS. 8A, 8B, 8C and 8D are views showing other examples of the cross-sectional structure of the display device according to the embodiments of the present disclosure.

FIG. 9, including parts (a)-(d), is a view showing still other examples of the cross-sectional structure of the display device according to the embodiments of the present disclosure.

FIG. 10 is a view showing a structure in which the display device including the cross-sectional structure of FIG. 9 is bent according to an embodiment of the present disclosure.

FIG. 11 is a view illustrating an example of a structure in which the cross-sectional structure illustrated in FIG. 4 is expanded according to an embodiment of the present disclosure.

FIG. 12 is a view showing a structure in which the display device including the cross-sectional structure of FIG. 11 is bent according to an embodiment of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A)” or “(B)” can be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element can be included in at least one of two or more elements that “are connected or coupled to,” “contact or overlap,” etc. each other.

When time relative terms, such as “after,” “subsequent to,” “next,” “before” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “can.”

The features of various embodiments of the present disclosure can be partially or entirely coupled to or combined with each other and can be interlocked and operated in technically various ways, and the embodiments can be carried out independently of or in association with each other. Also, the term “can” used herein includes all meanings and definitions of the term “may.”

Hereinafter, various embodiments of the present disclosure will be described in detail with reference to accompanying drawings.

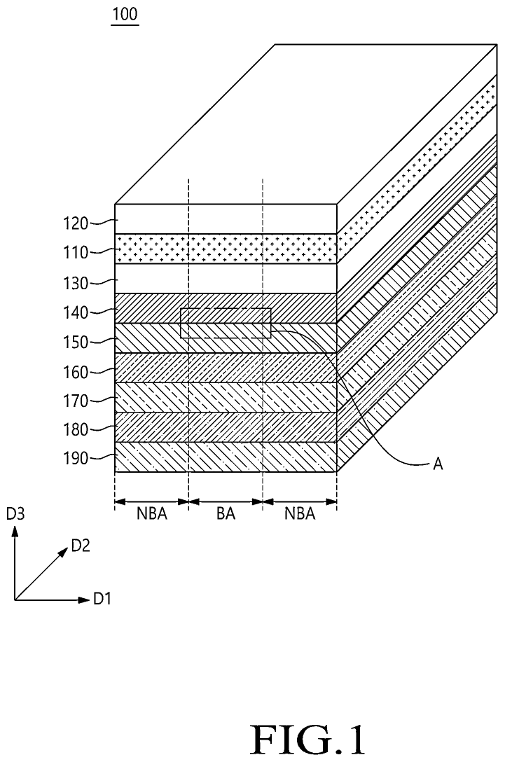

FIG. 1 is a view showing an example of the cross-sectional structure of a display device according to an embodiment of the present disclosure.

Referring to FIG. 1, a display device 100 can include a display panel 110, an upper polarizer 120, a lower polarizer 130, a plurality of substrates 150, 170 and 190 and a plurality of adhesive members 140, 160 and 180.

The display panel 110 can display an image. The display panel 110 can be an organic light emitting display panel. However, the present disclosure is not necessarily limited thereto, and the display panel 110 can be a liquid crystal display panel, etc.

The display panel 110 can include various components for displaying an image. For example, in the situation of an organic light emitting display panel, the display panel 110 can include light emitting elements.

The display panel 110 can be divided into a bending area BA where bending is performed in a direction D3 and a non-bending area NBA where bending is not performed.

The bending area BA can be defined as an area where the display device 100 including the display panel 110 is curved or bent about a certain axis through an action such as bending or sliding. The axis can be included in the bending area BA and can be an axis parallel to a direction D2.

The bending area BA can exist in the outer area of the display panel 110 or in the center area of the display panel 110 depending on the type of curving or bending, and is not limited to either one. Hereinafter, for the sake of convenience in explanation, it will be described as an example that the bending area BA is disposed in the center area of the display panel 110, but embodiments are not limited thereto.

In FIG. 1, only one bending area BA is shown in the display device 100. However, the present disclosure is not limited thereto, and a plurality of bending areas BA can exist. The width of the bending area BA can be narrower or wider than the width of the non-bending area NBA.

The non-bending area NBA as an area except for the bending area BA can mean an area where the display device 100 is not curved or bent.

A plurality of non-bending areas NBA can exist as shown in FIG. 1, or only one non-bending area NBA can exist.

The upper polarizer 120 and the lower polarizer 130 can be disposed on and under, respectively, the display panel 110.

Depending on the type of a display panel, a polarizer can play the role of adjusting a direction in which light travels or preventing light from outside a display device from being reflected to deteriorate visibility. For example, in the situation of an organic light emitting display panel, a polarizer can be disposed on or under the display panel 110 depending on the emission type of the display panel 110 to prevent visibility from deteriorating due to external light, and in the situation of a liquid crystal display panel, polarizers can be disposed both on and under the display panel 110 to adjust the path of light.

In FIG. 1, a situation where polarizers are disposed both on and under the display panel 110 is shown. However, the present disclosure is not necessarily limited thereto, and depending on the type of the display panel 110, either one of the upper polarizer 120 and the lower polarizer 130 can be omitted.

A first adhesive member 140 can be disposed under the lower polarizer 130. The first adhesive member 140 can play the role of adhering various layers existing inside the display device 100.

The first adhesive member 140 can be made of a transparent material, and can be made of a material such as an acrylic-based, silicone-based or urethane-based material.

The first adhesive member 140 can be an optically clear adhesive (OCA) of a film form or an optically clear resin (OCR) of an amorphous liquid form, but is not necessarily limited to either one. Hereinafter, it will be described as an example that the first adhesive member 140 is an OCA, but embodiments are not limited thereto.

As shown in FIG. 1, the first adhesive member 140 can adhere the lower polarizer 130 and a first substrate 150. For example, first adhesive member 140 can be disposed between the lower polarizer 130 and a first substrate 150.

The first substrate 150 can be disposed under the first adhesive member 140.

The first substrate 150 can play the role of a support for maintaining the shape of the display device 100. The first adhesive member 140 and the first substrate 150 can be adhered to each other.

The first substrate 150 can be made of a material such as polyethylene terephthalate (PET) or polyimide (PI), but is not necessarily limited thereto and can also be made of a metal material.

A second substrate 170 and a third substrate 190 can be further disposed below the first substrate 150. A second adhesive member 160 and a third adhesive member 180 can be further disposed between the first substrate 150 and the second substrate 170 and between the second substrate 170 and the third substrate 190 to adhere the respective substrates to each other.

The second substrate 170 and the third substrate 190 can be made of the same material and serve a same type of role as the first substrate 150. The second adhesive member 160 and the third adhesive member 180 can be made of the same material and serve the same type of role as the first adhesive member 140.

In FIG. 1, the second substrate 170, the third substrate 190, the second adhesive member 160 and the third adhesive member 180 are shown. However, the present disclosure is not necessarily limited thereto, and depending on the type of the display device 100, at least one substrate and adhesive member can be additionally disposed or can be omitted. Also, as the occasion demands, at least one substrate and adhesive member can be additionally disposed on the upper polarizer 120.

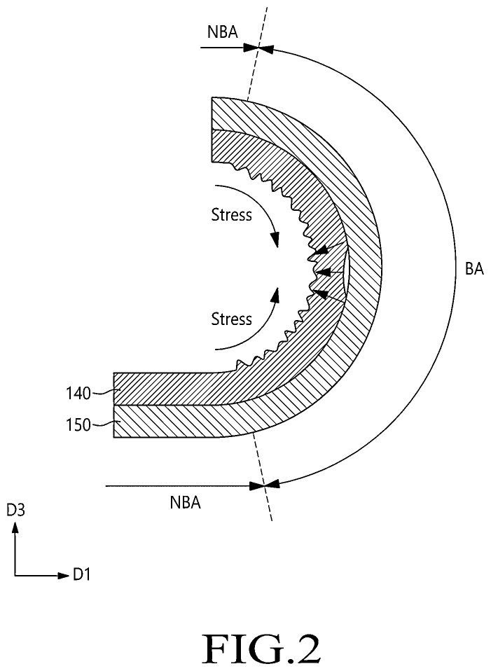

FIG. 2 is an enlarged view of a part A of FIG. 1, showing a structure in which the display device is bent.

Referring to FIG. 2, the display device 100 can be bent as shown in FIG. 2 in the bending area BA. FIG. 2 shows only a partial structure of the display device 100, that is, a structure in which the first adhesive member 140 and the first substrate 150 are bent, but this is for the sake of convenience in explanation. The entire display device 100 shown in FIG. 1 can be bent as shown in FIG. 2 in the bending area BA.

For example, the first substrate 150 of the display device 100 can be bent in the direction D3 by being slid as shown in FIG. 2.

When the first adhesive member 140 is adhered to the first substrate 150, the first adhesive member 140 can be bent together with the first substrate 150.

When the first adhesive member 140 is bent in the direction D3, the upper surface of the first adhesive member 140 shrinks more than the lower surface of the first adhesive member 140, that is, the surface of the first adhesive member 140 which contacts the first substrate 150. Therefore, as stress due to shrinkage is concentrated on the upper surface of the first adhesive member 140, and a phenomenon in which the upper surface of the first adhesive member 140 is distorted can occur.

When the stress due to shrinkage increases, a phenomenon can occur in which the lower surface of the first adhesive member 140 is not properly attached to the first substrate 150 and delaminates from the first substrate 150. For example, when the display device is bent, one side of the first adhesive member 140 may bunch up and ripple in the bending area BA while the opposite side of first adhesive member 140 may shrink and start to peel away from the first substrate 150.

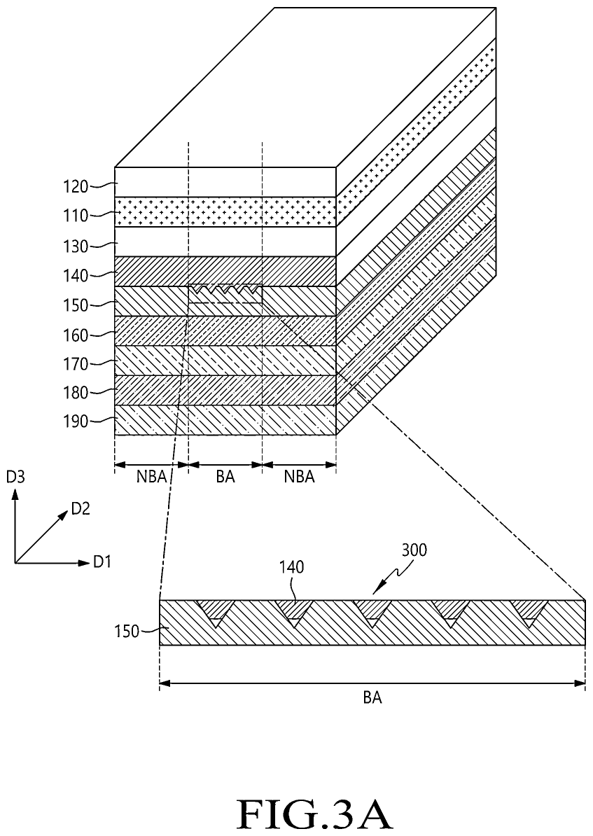

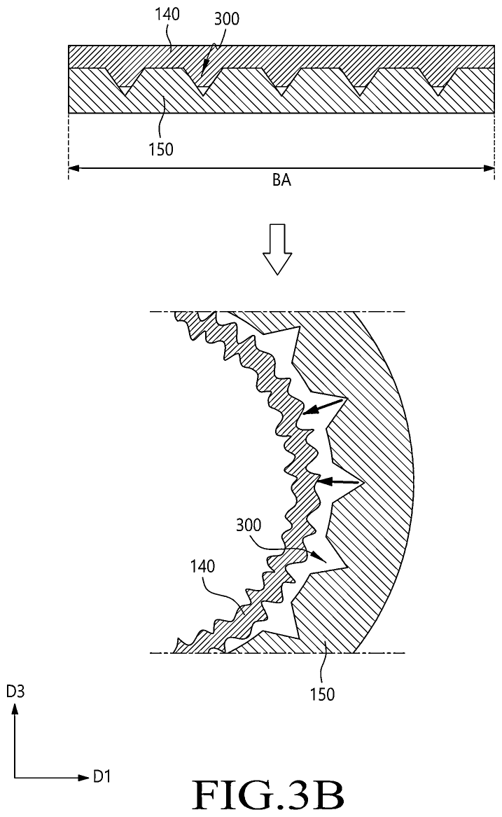

According to one way to solve these problems, a straight pattern 300 (see FIGS. 3A and 3B) is formed in the first substrate 150.

The straight pattern 300 can mean a pattern in which each side surface of a pattern has a slope of a constant angle (e.g., flat sided grooves in the first substrate 150).

FIG. 3A is a view showing an example of the cross-sectional structure of a comparative example display device and a partially enlarged structure thereof. FIG. 3B is a view showing a structure in which the display device having the cross-sectional structure of FIG. 3A is bent.

The display device shown in FIG. 3A is the same as the display device 100 shown in FIG. 1 except that the straight pattern 300 is disposed in the first substrate 150, and thus, repeated description will be omitted.

Referring to FIG. 3A, the straight pattern 300 can be disposed on the upper surface of the first substrate 150. The straight pattern 300 can also be disposed on the lower surface of the first substrate 150 depending on a bending direction.

The straight pattern 300 can be disposed in the bending area BA.

When the straight pattern 300 is disposed on the upper surface of the first substrate 150, the first adhesive member 140 can be disposed to fill the interior of the straight pattern 300. The first adhesive member 140 can be adhered onto the first substrate 150 through a roll lamination process. However, the present disclosure is not necessarily limited thereto, and the first adhesive member 140 can be adhered using a molding method, etc.

Referring to FIG. 3B, when the first substrate 150 and the first adhesive member 140 included in the display device 100 are bent in the direction D3 in the bending area BA, the first adhesive member 140 can become separated from the first substrate 150 and begin to peel away.

For example, when the first substrate 150 is bent in the direction D3, as the widths of straight patterns 300 decrease (e.g., when the flat angle sides between to squeeze together in a direction towards each other), a problem can arise in that the first adhesive member 140 which fills the interiors of the straight patterns 300 is pushed out of the straight patterns 300 (e.g., the first adhesive member 140 can get squished out of the grooves and delaminate). In other words, because the side surfaces of the straight pattern 300 have the slope of the constant angle, when the first substrate 150 is bent, the first adhesive member 140 may no longer be trapped in the interiors of the straight patterns 300, and can be pushed out of the straight patterns 300. Therefore, a phenomenon in which the first adhesive member 140 delaminates from the first substrate 150 can occur.

Hereunder, measures capable of solving these problems will be described with reference to a display device according to embodiments of the present disclosure, as detailed below.

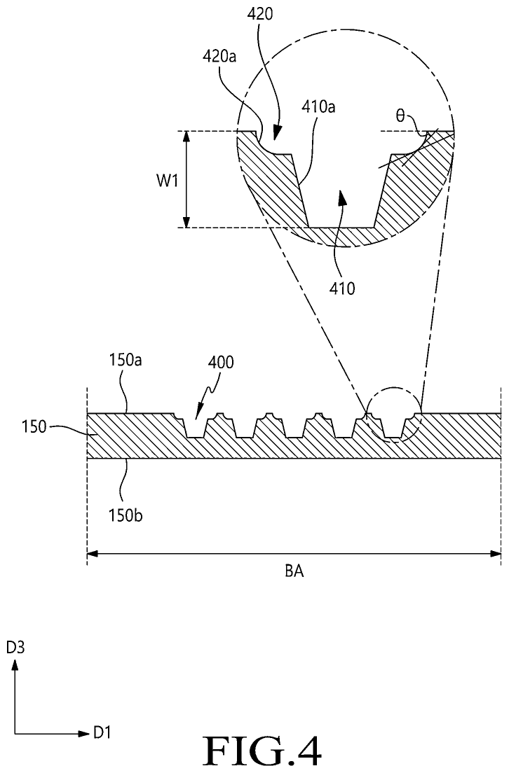

FIG. 4 is a view illustrating an example of a part of the cross-sectional structure of a display device according to embodiments of the present disclosure.

The first substrate 150 shown in FIG. 4 is the same as the first substrate 150 described above with reference to FIGS. 3A and 3B except for that the first substrate 150 includes a first groove pattern 400 instead of the straight pattern 300, and thus, repeated description will be omitted.

Referring to FIG. 4, the first substrate 150 can include at least one first groove pattern 400. The first groove pattern 400 can be formed on a first surface 150a or a second surface 150b of the first substrate 150. The first groove pattern 400 can be in the bending area BA.

The first surface 150a is a surface which faces the lower surface of the display panel 110, and the second surface 150b is a surface which faces away from the display panel 110. The first surface 150a can be closer to the display panel 110 than the second surface 150b, but embodiments are not limited thereto.

When the first substrate 150 is bent in the direction D3, the first groove pattern 400 can be on the first surface 150a. When the first substrate 150 is bent in a direction opposite to the direction D3, the first groove pattern 400 can be on the second surface 150b.

Hereinafter, for the sake of convenience in explanation, it will be described as an example that the first groove pattern 400 is disposed on the first surface 150a, but embodiments are not limited thereto.

The first groove pattern 400 can include a first part 410 which is recessed from the first surface 150a and a second part 420 on the first part 410. For example, the first groove pattern 400 can for a type of “head and shoulders” pattern that extends into the first substrate 150 (e.g., 410 can correspond to the head and 420 can correspond to the shoulders). In other words, a cross section of the first groove pattern 400 can have a bottle neck type of shape. The total depth of the first groove pattern 400 including the first part 410 and the second part 420 can be W1. The depth of the first part 410 can be larger than the depth of the second part 420, but is not limited thereto.

The first part 410 can include a bottom surface which is recessed from the first surface 150a and first sidewalls 410a on both side surfaces connected to the bottom surface. The first part 410 can be defined by the bottom surface and the first sidewalls 410a on both side surfaces.

The width in a direction D1 of the first part 410 can gradually increase in the direction D3. In other words, the width of the first part 410 can be smallest at the bottom surface, and can be largest at the boundary between the first part 410 and the second part 420. However, the present disclosure is not necessarily limited thereto. For example, the first groove pattern 400 can have a tapered shaped as it extends into the first substrate 150.

The second part 420 can be located on the first part 410.

The second part 420 can include second sidewalls 420a on both side surfaces. The second part 420 can be defined by the second sidewalls 420a on both side surfaces and a portion where the first surface 150a of the first substrate 150 is opened by the first groove pattern 400. For example, the second part 420 can be a type of hole that is in communication with the first part 410.

The second sidewall 420a of the second part 420 can have an outwardly convex shape.

The width in the direction D1 of the second part 420 can be larger than the width in the direction D1 of the first part 410. Namely, the width of the second part 420 can be larger than a width at the boundary between the second part 420 and the first part 410.

As the second sidewall 420a has the outwardly convex shape, an angle θ formed by a straight line which is tangent to the second sidewall 420a and the first surface 150a increases as a point where the straight line is tangent to the second sidewall 420a is close to the first surface 150a.

As the first groove pattern 400 includes the first part 410 and the second part 420, even when the first substrate 150 is bent, the first adhesive member 140 can be prevented from delaminating from the first substrate 150. This advantage is described in more detail below.

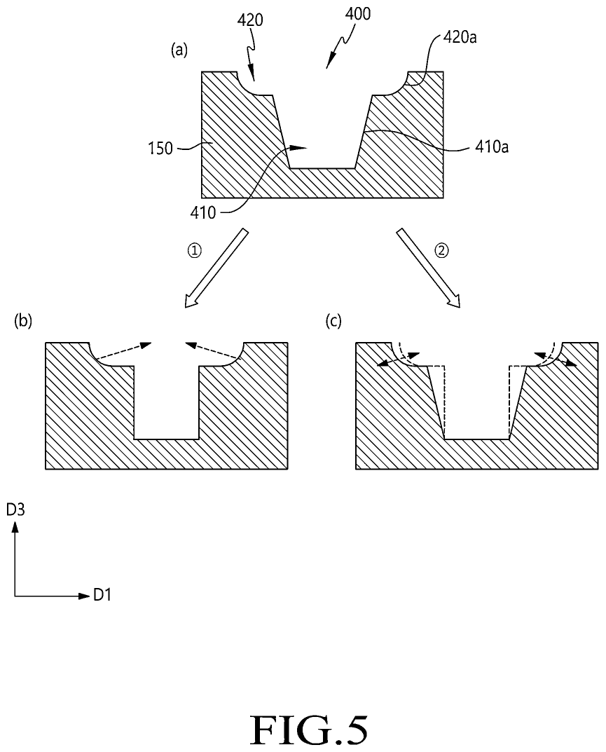

FIG. 5 is a view showing an example in which the cross-sectional structure of FIG. 4 is deformed.

Referring to FIG. 5, when the first substrate 150 is bent, the shape of the first groove pattern 400 can change.

When the first substrate 150 is bent (\hat{1})), the width of the first groove pattern 400 can decrease. As the width of the first groove pattern 400 decreases, each of the distance between the first sidewalls 410a and the distance between the second sidewalls 420a can decrease (e.g., when the display device is bent, the sides of the groove can move closer to each other).

When the first substrate 150 is bent and is then straightened through repeated movements (e.g., bent back and forth) (\hat{2}), the width of the first groove pattern 400 can decrease and then return to an original width. In addition, each of the distance between the first sidewalls 410a and the distance between the second sidewalls 420a can decrease and then return to its original distance. As can be seen in \hat{2}, the shape of the first groove pattern 400 can be freely changed according to repeated movements, and thus, it is possible to prevent the shape of the first substrate 150 from being distorted due to repeated movements.

As the first substrate 150 is bent in the direction D3, the width of the first groove pattern 400 can decrease. At this time, since the first substrate 150 is bent in the direction D3, the width of the first groove pattern 400 decreases more at a portion closer to the first surface 150a (e.g., at the upper portion of the groove). That is to say, the width of a portion where the second part 420 is connected to the first surface 150a can decrease most.

Accordingly, the width of the portion where the second part 420 is connected to the first surface 150a can become smaller than the widths of other portions of the second part 420. In other words, the width of the second part 420 can be largest in the middle portion thereof.

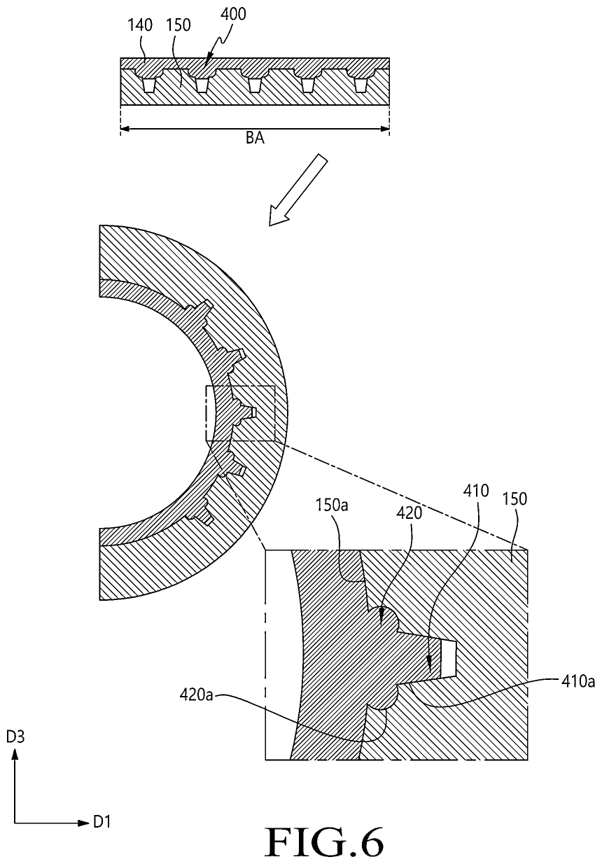

FIG. 6 is a view showing a structure in which the display device including the cross-sectional structure of FIG. 4 is bent according to an embodiment of the present disclosure.

Referring to FIG. 6, the first adhesive member 140 can be disposed to fill a part of the first groove pattern 400.

When the first substrate 150 is bent in the direction D3, the first adhesive member 140 can fill the first groove pattern 400 more than before the first substrate 150 is bent. In other words, when the display device is bent, rather than squishing the first adhesive member 140 out of the first groove pattern 400, the shape and depth of the first groove pattern 400 can provide an expansion space at the bottom of the first groove pattern 400 and the first adhesive member 140 can be squished into the first groove pattern 400 by extending further towards the bottom of the first groove pattern 400, which can prevent any delamination or undue distortion from occurring.

As the second part 420 of the first groove pattern 400 has the outwardly convex shape, it is possible to prevent bubbles from being generated when the first adhesive member 140 fills the first groove pattern 400. In addition, since the second part 420 has a larger surface area, an area in contact with the first adhesive member 140 increases, and thus, the adhesive strength between the first adhesive member 140 and the first substrate 150 can increase.

Furthermore, since an area by which the first adhesive member 140 fills the first groove pattern 400 is larger than an area by which the first adhesive member 140 fills the straight pattern 300, the first adhesive member 140 can be absorbed more into the first groove pattern 400 (e.g., the first adhesive member 140 can be squished deeper into the first groove pattern 400, rather than being squished out of the groove), and a degree by which the upper surface of the first adhesive member 140 shrinks further decreases. Therefore, stress concentrated on the upper surface of the first adhesive member 140 can be reduced more, thereby more effectively solving a problem that the upper surface is distorted, preventing ripples from forming, maintaining image quality, and increasing a lifespan of the display device.

In addition, when the first substrate 150 is bent in the direction D3, as the width of a portion where the second part 420 is connected to the first surface 150a becomes smaller than the widths of other portions of the second part 420, a clamping effect can occur. The clamping effect is an effect that tightens the entrance of a space to prevent an object filled in the space from being discharged. In other words, the shape of the first groove pattern 400 can allow the first groove pattern 400 to grip or pinch the first adhesive member 140 so that the first adhesive member 140 is held in place while the display device is being bent. As the width of the portion where the second part 420 is connected to the first surface 150a decreases, the first groove pattern 400 can effectively trap, within the first groove pattern 400, the first adhesive member 140 introduced into the first groove pattern 400. Accordingly, even when repeated bending occurs, since the first adhesive member 140 which fills the interior of the first groove pattern 400 can be prevented from being pushed out of the first groove pattern 400, it is possible to prevent a phenomenon in which the first adhesive member 140 delaminates from or comes off the first substrate 150.

The effects described above can be more effective when the first adhesive member 140 has a low storage modulus. Namely, when the first adhesive member 140 has a low storage modulus, because the adhesive member 140 can be better absorbed into the first groove pattern 400, the above-described effects can be maximized. For example, the storage modulus of the first adhesive member 140 can be equal to or less than 105 Pa. However, the present disclosure is not necessarily limited thereto.

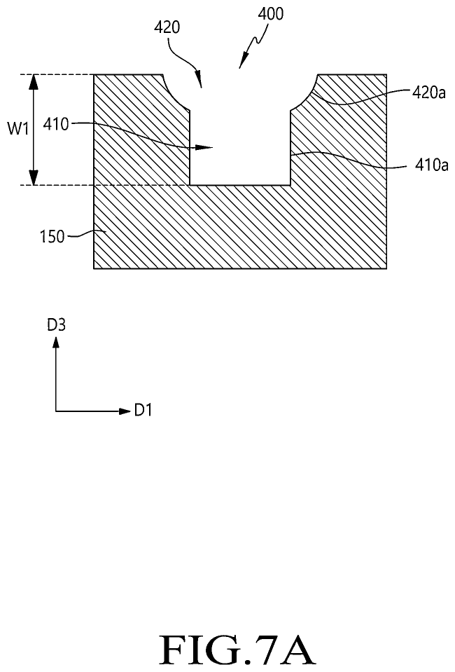

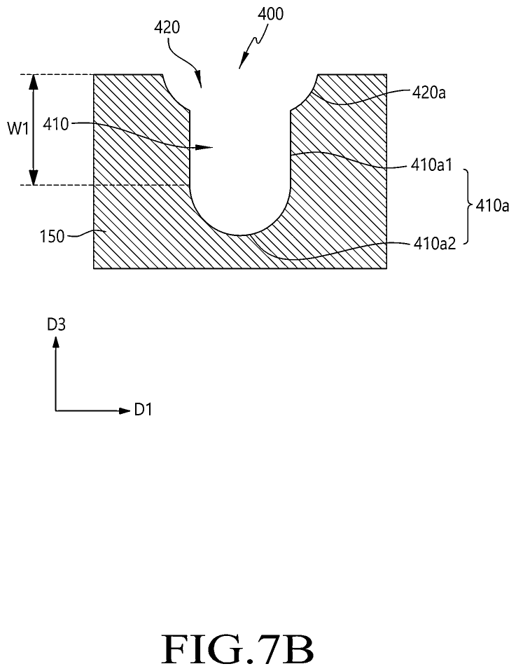

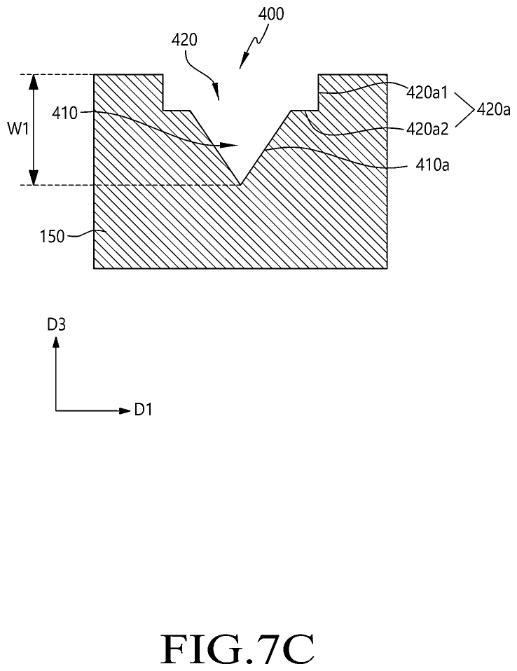

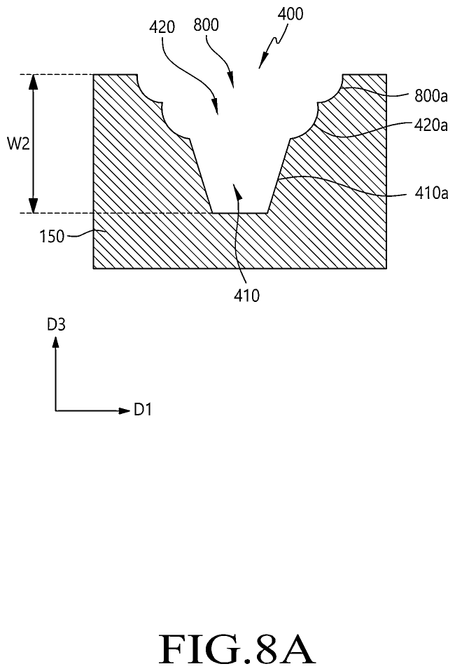

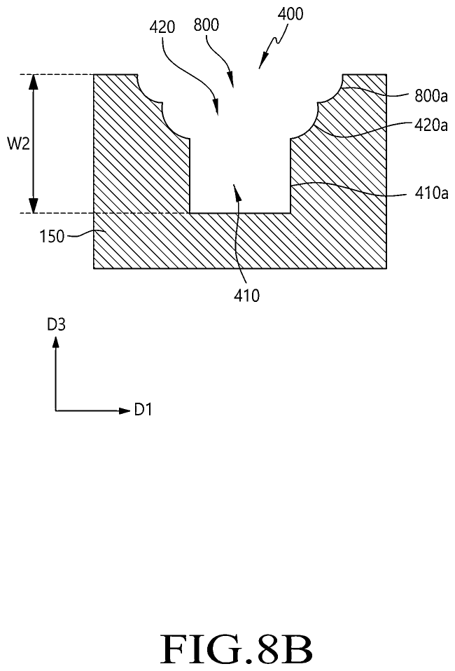

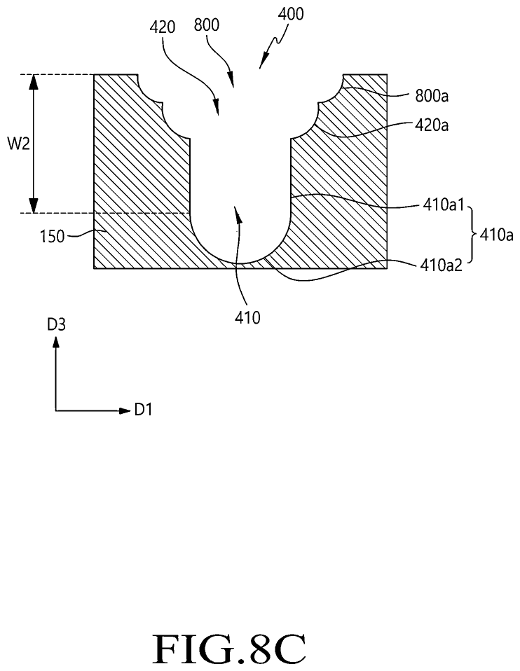

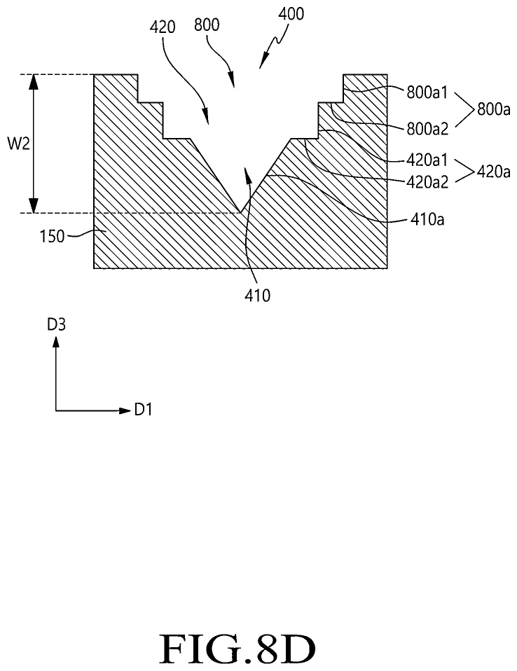

FIGS. 7A, 7B, 7C and 8A, 8B, 8C and 8D are views showing other examples of the cross-sectional structure of the display device according to the embodiments of the present disclosure.

The first groove pattern 400 shown in FIGS. 7A to 7C is the same as the first groove pattern 400 shown in FIGS. 4 and 5 except that the shape of the first part 410 or the second part 420 is changed, and thus, repeated description will be omitted.

Referring to FIG. 7A, the width of the first part 410 of the first groove pattern 400 can be constant. That is to say, the first sidewall 410a of the first part 410 can be perpendicular to the direction D1.

When the first substrate 150 is bent in the direction D3, the width of the upper end portion of the first part 410, that is, the width of a portion where the first part 410 is connected to the second part 420, can decrease to a greater extent than the width of the bottom surface of the first part 410.

Since the widths of the upper end portion and the bottom surface of the first part 410 before the first substrate 150 is bent are the same, the width of the upper end portion of the first part 410 after the first substrate 150 is bent can be smaller than the width of the bottom surface.

As the width of the upper end portion of the first part 410 becomes smaller than the width of the bottom surface, the first groove pattern 400 can better trap and hold the first adhesive member 140 therein. Accordingly, by preventing the first adhesive member 140 from being pushed out of the first groove pattern 400, it is possible to more effectively prevent a phenomenon in which the first adhesive member 140 delaminates from the first substrate 150.

Referring to FIG. 7B, the bottom surface of the first part 410 of the first groove pattern 400 can have an outwardly convex shape (e.g., a rounded head and shoulders shape). The first sidewall 410a of the first part 410 can include a straight portion 410a1 and a curved portion 410a2 which is connected to the straight portion 410a1.

The first part 410 of the first groove pattern 400 shown in FIG. 7B can have a shape in which the bottom surface in the first part 410 of the first groove pattern 400 shown in FIG. 7A is changed to the curved portion 410a2. In this situation, the length in the direction D3 of the straight portion 410a1 can be the same as the length of the first sidewall 410a of the first part 410 shown in FIG. 7A. However, the present disclosure is not necessarily limited thereto, and the length of the straight portion 410a1 can be different from the length of the first sidewall 410a of the first part 410 shown in FIG. 7A.

As the first groove pattern 400 shown in FIG. 7B includes the curved portion 410a2, the first part 410 can be recessed further or deeper from the first surface 150a of the first substrate 150 than the first part 410 shown in FIG. 7A.

When the first part 410 of the first groove pattern 400 includes the curved portion 410a2, an area where the first adhesive member 140 is adhered to the first groove pattern 400 can be wider than when the first part 410 does not include the curved portion 410a2, and thus, the first adhesive member 140 can be absorbed more into the first groove pattern 400 (e.g., a larger expansion area can be provided at the bottom of the first groove pattern 400). Accordingly, since a degree by which the upper surface of the first adhesive member 140 shrinks further decreases, stress concentrated on the upper surface of the first adhesive member 140 can be further reduced, thereby more effectively solving a problem that the upper surface is distorted.

In addition, the adhesive strength between the first adhesive member 140 and the first substrate 150 can increase, thereby preventing a phenomenon in which the first adhesive member 140 delaminates from the first substrate 150.

Referring to FIG. 7C, the width of the first part 410 of the first groove pattern 400 can gradually increase toward the upper end of the first part 410. The slope of the side surface of the first part 410 can be constant, but is not limited thereto.

The second part 420 of the first groove pattern 400 can have a shape which is recessed at a right angle. The second sidewall 420a of the second part 420 can include a first surface 420a1 which is perpendicular to the upper surface of the first substrate 150 and a second surface 420a2 which is connected to the first surface 420a1 and is perpendicular to the first surface 420a1.

Since the second part 420 of the first groove pattern 400 has the shape which is recessed at a right angle, compared to the situation where the second part 420 of the first groove pattern 400 has a curved sidewall as described above with reference to FIG. 7A, the first adhesive member 140 can be absorbed more into the second part 420 of the first groove pattern 400.

Therefore, when the first substrate 150 is bent, stress concentrated on the upper surface of the first adhesive member 140 can be further reduced, thereby more effectively solving a problem that the upper surface of the first adhesive member 140 is distorted.

Referring to FIG. 8A, the first groove pattern 400 can further include a third part 800 (e.g., a type of pointy or tapered head and rounded double shoulders pattern).

The total depth of the first groove pattern 400 including the first part 410, the second part 420 and the third part 800 can be W2. W2 can be larger than W1.

The third part 800 can be formed on the second part 420.

The third part 800 can include third sidewalls 800a on both side surfaces. The third part 800 can be defined by the third sidewalls 800a on both side surfaces and the boundary between the second part 420 and the third part 800.

The third sidewall 800a can have an outwardly convex shape. However, the present disclosure is not necessarily limited thereto.

The width of the third part 800 can be larger than the widths of the first part 410 and the second part 420. In other words, the width of the third part 800 can be larger than the width at the boundary between the first part 410 and the second part 420 and the width at the boundary between the second part 420 and the third part 800.

As the third sidewall 800a has the outwardly convex shape, an angle θ formed by a straight line which is tangent to the third sidewall 800a and the first surface 150a increases as a point where the straight line is tangent to the third sidewall 800a is close to the first surface 150a.

As the first substrate 150 is bent in the direction D3, the width of the first groove pattern 400 can decrease.

At this time, since the first substrate 150 is bent in the direction D3, the width of the first groove pattern 400 decreases more at a portion closer to the first surface 150a. Namely, the width of a portion where the third part 800 is connected to the first surface 150a can decrease most.

Accordingly, the width of the portion where the third part 800 is connected to the first surface 150a can become smaller than the widths of other portions of the third part 800. That is to say, the width of the third part 800 can be largest in the middle portion thereof.

As the first groove pattern 400 includes the third part 800, the depth of the first groove pattern 400 increases, and thus, the first adhesive member 140 can be absorbed more into the first groove pattern 400. As the first adhesive member 140 is absorbed more into the first groove pattern 400, the adhesion area between the first adhesive member 140 and the first substrate 150 increases, and thus, the adhesive strength between the first adhesive member 140 and the first substrate 150 can be further increased.

Moreover, since an area where the first adhesive member 140 fills the first groove pattern 400 increases more, the first adhesive member 140 can be absorbed more into the first groove pattern 400, and a degree by which the upper surface of the first adhesive member 140 shrinks further decreases. Therefore, stress concentrated on the upper surface of the first adhesive member 140 can be reduced more, thereby more effectively solving a problem that the upper surface is distorted.

In addition, since the width of a portion of the third part 800 can become larger than the width of the portion where the third part 800 of the first groove pattern 400 is connected to the first surface 150a, that is, since the third part 800 has a shape in which the middle portion of the third part 800 protrudes outward more than the upper end portion of the third part 800, a space that can trap the first adhesive member 140 therein can be added. Accordingly, the first adhesive member 140 which fills the interior of the first groove pattern 400 can be prevented from being pushed out of the first groove pattern 400, and it is possible to more effectively prevent a phenomenon in which the first adhesive member 140 delaminates from the first substrate 150.

Referring to FIG. 8B, the width of the first part 410 of the first groove pattern 400 can be constant. That is to say, the first sidewall 410a of the first part 410 can be perpendicular to the direction D1 (e.g., a type of flat or rectangular head and rounded double shoulders pattern).

The first groove pattern 400 shown in FIG. 8B is the same as the first groove pattern 400 illustrated in FIG. 8A except that the shape of the first part 410 is changed and the changed shape of the first part 410 is the same as the shape of the first part 410 shown in FIG. 7A, and thus, repeated description will be omitted.

As the width of the upper end portion of the first part 410 becomes smaller than the width of the bottom surface, the first groove pattern 400 can better trap the first adhesive member 140 therein. Accordingly, by preventing the first adhesive member 140 from being pushed out of the first groove pattern 400, it is possible to more effectively prevent a phenomenon in which the first adhesive member 140 delaminates from the first substrate 150.

Referring to FIG. 8C, the bottom surface of the first part 410 of the first groove pattern 400 can have an outwardly convex shape. The first sidewall 410a of the first part 410 can include a straight portion 410a1 and a curved portion 410a2 which is connected to the straight portion 410a1 (e.g., a type of rounded head and rounded double shoulders pattern).

The first groove pattern 400 shown in FIG. 8C is the same as the first groove pattern 400 illustrated in FIG. 8A except that the shape of the first part 410 is changed and the changed shape of the first part 410 is the same as the shape of the first part 410 shown in FIG. 7B, and thus, repeated description will be omitted.

When the first part 410 of the first groove pattern 400 includes the curved portion 410a2, an area where the first adhesive member 140 is adhered to the first groove pattern 400 can be wider than when the first part 410 does not include the curved portion 410a2, and thus, the first adhesive member 140 can be absorbed more into the first groove pattern 400. Accordingly, since a degree by which the upper surface of the first adhesive member 140 shrinks further decreases, stress concentrated on the upper surface of the first adhesive member 140 can be further reduced, thereby more effectively solving a problem that the upper surface is distorted.

In addition, the adhesive strength between the first adhesive member 140 and the first substrate 150 can increase, thereby preventing a phenomenon in which the first adhesive member 140 delaminates from the first substrate 150.

Referring to FIG. 8D, the width of the first part 410 of the first groove pattern 400 can gradually increase toward the upper end of the first part 410 (e.g., a type of pointy or triangular head and rectangular double shoulders pattern). The slope of the side surface of the first part 410 can be constant, but is not limited thereto.

As described above with reference to FIG. 7C, the second part 420 of the first groove pattern 400 can have a shape which is recessed at a right angle.

The third part 800 of the first groove pattern 400 can have a shape which is recessed at a right angle. In other words, the third part 800 can have the same shape as the second part 420.

The third sidewall 800a of the third part 800 can include a first surface 800a1 which is perpendicular to the upper surface of the first substrate 150 and a second surface 800a2 which is connected to the first surface 800a1 and is perpendicular to the first surface 800a1.

Since the second part 420 and the third part 800 of the first groove pattern 400 have the shapes which are recessed at a right angle, compared to the situation where the second part 420 and the third part 800 of the first groove pattern 400 have curved sidewalls as described above with reference to FIGS. 8A to 8C, the first adhesive member 140 can be absorbed more into the second part 420 and the third part 800 of the first groove pattern 400.

Therefore, when the first substrate 150 is bent, stress concentrated on the upper surface of the first adhesive member 140 can be further reduced, thereby more effectively solving a problem that the upper surface of the first adhesive member 140 is distorted.

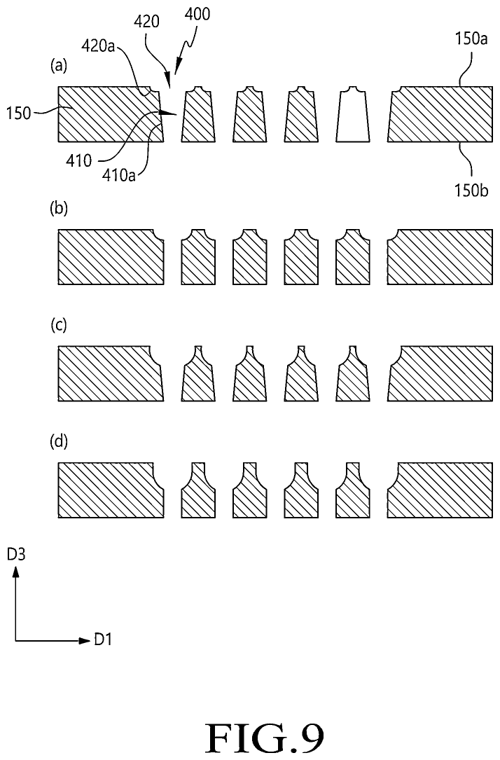

FIG. 9 is a view showing still other examples of the cross-sectional structure of the display device according to the embodiments of the present disclosure.

The first groove pattern 400 shown in FIGS. 9 is the same as the first groove pattern 400 shown in FIGS. 4 and 7A except a structure in which the first part 410 passes through the first substrate 150, and thus, repeated description will be omitted. For example, the first groove pattern 400 can penetrate all the way through opposite sides of the first substrate 150.

Referring to FIG. 9, including parts (a)-(d), the first part 410 of the first groove pattern 400 can pass through the first substrate 150.

As shown in part (a) and part (b) of FIG. 9, the first groove pattern 400 can pass through the first substrate 150 as the depth of the first part 410 increases. As shown in part (c) and part (d) of FIG. 9, the first groove pattern 400 can pass through the first substrate 150 as the depths of both the first part 410 and the second part 420 increase (e.g., a cross section of the first groove pattern 400 can have a bottle neck type of shape).

When the depth of the first part 410 increases as shown in part (a) and part (b) of FIG. 9, the first adhesive member 140 can be absorbed more from the upper surface 150a of the first substrate 150. Therefore, an area where the first adhesive member 140 and the first groove pattern 400 are adhered to each other can increase.

When the depths of both the first part 410 and the second part 420 increase as shown in part (c) and part (d) of FIG. 9, compared to part (a) and part (b) of FIG. 9, the area of the second sidewall 420a of the second part 420 becomes larger, and an area where the first adhesive member 140 and the first substrate 150 can be adhered to each other can further increase.

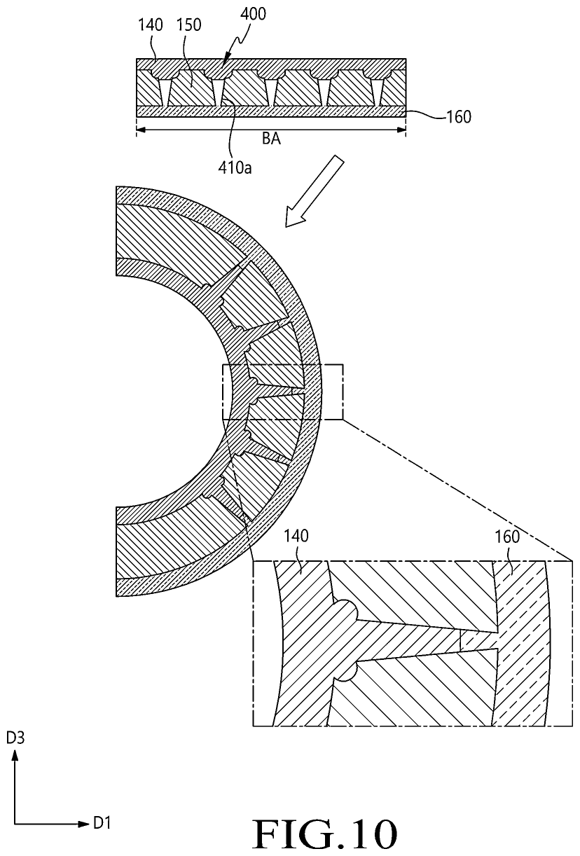

FIG. 10 is a view showing a structure in which the display device including the cross-sectional structure of FIG. 9 is bent.

Referring to FIG. 10, the first adhesive member 140 can be disposed on the first substrate 150.

When the first substrate 150 is bent in the direction D3 as described above, since the first groove pattern 400 has a passing-through structure, the first adhesive member 140 can be absorbed deeper into the first groove pattern 400. Accordingly, the adhesion area between the first substrate 150 and the first adhesive member 140 can increase.

Hence, as described above, it is possible to more effectively prevent a problem that the upper surface of the first adhesive member 140 is distorted.

In addition, it is possible to more effectively prevent a phenomenon in which the first adhesive member 140 delaminates from the first substrate 150.

Referring to FIG. 10, the second adhesive member 160 can be further disposed under the first substrate 150.

When the first substrate 150 is bent in the direction D3, since the first groove pattern 400 has the passing-through structure, the second adhesive member 160 can be partially absorbed into the first groove pattern 400. For example, during bending, the first adhesive member 140 and the second adhesive member 160 can squish into the first groove pattern 400 from opposite sides.

One part of the second adhesive member 160 which is absorbed into the first groove pattern 400 can adhere to the first substrate 150, and the other part can adhere to the first adhesive member 140.

Namely, since the first groove pattern 400 has the passing-through structure, the first adhesive member 140 can adhere not only to the first substrate 150 but also to the second adhesive member 160, so that when bending occurs, the first adhesive member 140 can be better trapped in the first groove pattern 400. Therefore, it is possible to better prevent a phenomenon in which the first adhesive member 140 delaminates from the first substrate 150.

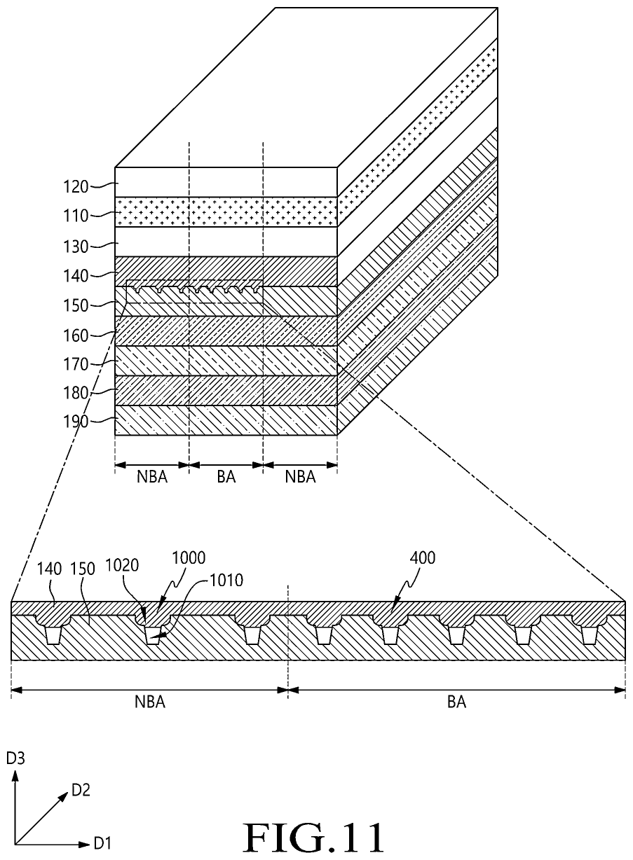

FIG. 11 is a view illustrating an example of a structure in which the cross-sectional structure illustrated in FIG. 4 is expanded, according to an embodiment of the present disclosure.

The cross-sectional structure of the display device 100 shown in FIG. 11 is the same as the cross-sectional structure shown in FIG. 4 except for that at least one second groove pattern 1000 is disposed in the non-bending area NBA, and thus, repeated description will be omitted.

Referring to FIG. 11, at least one second groove pattern 1000 can be disposed in the non-bending area NBA.

The second groove pattern 1000 can be the same pattern as the first groove pattern 400. That is to say, the second groove pattern 1000 can include a first part 1010 and a second part 1020 on the first part 1010.

The first part 1010 of the second groove pattern 1000 can have the same pattern as the first part 410 of the first groove pattern 400. The second part 1020 of the second groove pattern 1000 can have the same pattern as the second part 420 of the first groove pattern 400. However, the present disclosure is not limited thereto, and at least one of the respective parts of the second groove pattern 1000 can be different from at least one of the respective parts of the first groove pattern 400.

Second groove patterns 1000 can be disposed at a lower density than first groove patterns 400. In other words, the number of second groove patterns 1000 per unit area disposed in the non-bending area NBA can be smaller than the number of first groove patterns 400 per unit area disposed in the bending area BA.

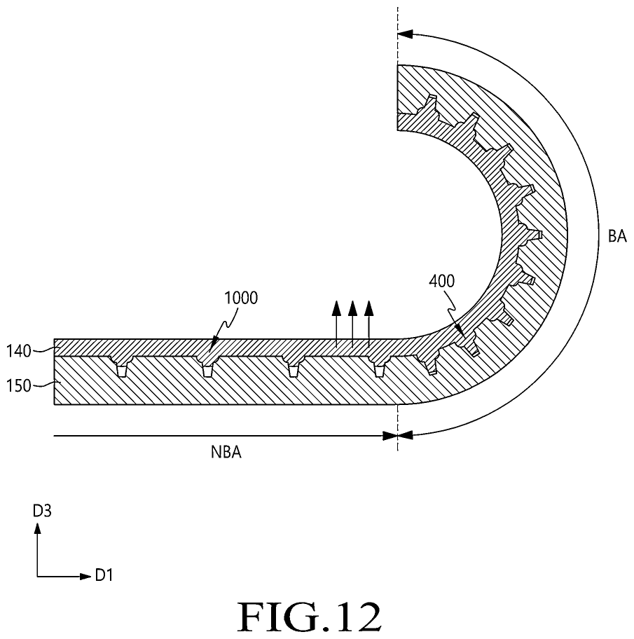

FIG. 12 is a view showing a structure in which the display device including the cross-sectional structure of FIG. 11 is bent, according to an embodiment of the present disclosure.

Referring to FIG. 12, when the display device 100 is bent in the bending area BA, some bending can also occur at the boundary between the bending area BA and the non-bending area NBA and in the non-bending area NBA near the boundary.

When bending occurs at the boundary between the bending area BA and the non-bending area NBA and in the non-bending area near the boundary, as stress is concentrated on the boundary between the bending area BA and the non-bending area NBA and the non-bending area near the boundary, a phenomenon can occur in which the upper surface of the first adhesive member 140 is distorted, and as shown in FIG. 12, a phenomenon can occur in which the first adhesive member 140 delaminates from the first substrate 150. In this way, stress that may occur at the boundary between the bending area BA and the non-bending area NBA, during bending, can be alleviated.

When the second groove pattern 1000 is disposed in the non-bending area NBA, the first adhesive member 140 which is disposed at the boundary between the bending area BA and the non-bending area NBA and in the non-bending area NEA near the boundary can be absorbed into the second groove pattern 1000. Therefore, it is possible to prevent a phenomenon in which the upper surface of the first adhesive member 140 is distorted in the non-bending area NBA, and since the adhesion area between the first adhesive member 140 and the first substrate 150 is widened, it is possible to prevent a phenomenon in which the first adhesive member 140 delaminates from the first substrate 150 in the non-bending area NBA.

In addition, as described above with respect to the first groove pattern 400 with reference to FIG. 5, since the shape of the second groove pattern 1000 can be freely changed according to repeated movements, it is possible to prevent the shape of the first substrate 150 from being distorted due to repeated movements in the non-bending area NBA.

Brief description of the embodiments of the present disclosure described above is as follows.

According to embodiments of the present disclosure, a display device can include a display panel, a substrate having a first surface which faces one surface of the display panel and a second surface which faces away from the first surface, and including a plurality of groove patterns which are located on at least one of the first surface or the second surface, each of the plurality of groove patterns including a first part which has a width equal to or smaller than a reference width and a second part which has a width equal to or larger than the reference width and which has an outwardly convex shape, and an adhesive member disposed on the substrate to fill the groove patterns.

In the display device according to the embodiments of the present disclosure, the first surface can be closer to the display panel than the second surface, the plurality of groove patterns can be disposed on the first surface, and the second part can be connected to the first surface.

In the display device according to the embodiments of the present disclosure, an angle formed by a straight line tangent to a sidewall of the second part and the first surface can increase as a location where the straight line is tangent to the sidewall of the second part is close to the first surface.

In the display device according to the embodiments of the present disclosure, at least one width of widths of the second part can be larger than a width of a portion where the second part is connected to the first surface.

In the display device according to the embodiments of the present disclosure, the substrate can include a bending area which is bent about an axis and a non-bending area, the plurality of groove patterns can include a plurality of first groove patterns which are disposed in the bending area and a plurality of second groove patterns which are disposed in the non-bending area, and the plurality of second groove patterns can be disposed at a lower density than the plurality of first groove patterns.

In the display device according to the embodiments of the present disclosure, a width of a portion where the first groove pattern is connected to the first surface can be smaller than a width of a portion where the second groove pattern is connected to the first surface.

In the display device according to the embodiments of the present disclosure, at least two widths of each of the plurality of first groove patterns can be different from each other.

In the display device according to the embodiments of the present disclosure, each of the plurality of groove patterns can be formed to pass through the substrate.

In the display device according to the embodiments of the present disclosure, a storage modulus of the adhesive member can be equal to or less than 105 Pa.

According to embodiments of the present disclosure, a display device can include a display panel; a substrate having a first surface which faces one surface of the display panel and a second surface which faces away from the first surface, and including a plurality of groove patterns which are located on at least one of the first surface or the second surface, each of the plurality of groove patterns including a first part which has a surface at least partially flat toward an outside and a second part which has an outwardly convex shape; and an adhesive member disposed on the substrate to fill the groove patterns.

In the display device according to the embodiments of the present disclosure, the first surface can be closer to the display panel than the second surface, the plurality of groove patterns can be disposed on the first surface, and the second part can be connected to the first surface.

In the display device according to the embodiments of the present disclosure, an angle formed by a straight line tangent to a sidewall of the second part and the first surface can increase as a location where the straight line is tangent to the sidewall of the second part is close to the first surface.

In the display device according to the embodiments of the present disclosure, at least one width of widths of the second part can be larger than a width of a portion where the second part is connected to the first surface.

In the display device according to the embodiments of the present disclosure, the substrate can include a bending area which is bent about an axis and a non-bending area, the plurality of groove patterns can include a plurality of first groove patterns which are disposed in the bending area and a plurality of second groove patterns which are disposed in the non-bending area, and the plurality of second groove patterns can be disposed at a lower density than the plurality of first groove patterns.

In the display device according to the embodiments of the present disclosure, each of the plurality of groove patterns can be formed to pass through the substrate.

According to embodiments of the present disclosure, a display device can include a display panel, a substrate having a first surface which faces one surface of the display panel and a second surface which faces away from the first surface, and including a plurality of groove patterns which are located on at least one of the first surface or the second surface, each of the plurality of groove patterns including at least partially a part which has an outwardly convex shape, and an adhesive member disposed on the substrate to fill the groove patterns.

In the display device according to the embodiments of the present disclosure, the first surface can be closer to the display panel than the second surface, the plurality of groove patterns can be disposed on the first surface, and the part which has the convex shape can be connected to the first surface.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a display panel including a plurality of subpixels;
a substrate having a first surface facing the display panel and a second surface facing away from the first surface;
a plurality of groove patterns on at least one of the first surface of the substrate or the second surface of the substrate, each of the plurality of groove patterns including a first part having a width equal to or smaller than a reference width and a second part having a width equal to or larger than the reference width, the second part having an outwardly convex shape; and
an adhesive member disposed on the substrate to fill the plurality of groove patterns.

2. The display device of claim 1, wherein the first surface of the substrate is closer to the display panel than the second surface of the substrate, the plurality of groove patterns are on the first surface of the substrate, and the second part is connected to or adjacent to the first surface of the substrate.

3. The display device of claim 1, wherein an angle formed by a straight line tangent to a sidewall of the second part and the first surface increases as a location where the straight line is tangent to the sidewall of the second part is close to the first surface.

4. The display device of claim 1, wherein at least one width of widths of the second part is larger than a width of a portion where the second part is connected to the first surface.

5. The display device of claim 1, wherein the substrate includes a bending area configured to bend about an axis and a non-bending area,
wherein the plurality of groove patterns include a plurality of first groove patterns in the bending area and a plurality of second groove patterns in the non-bending area, and
wherein the plurality of second groove patterns are disposed at a lower density than the plurality of first groove patterns.

6. The display device of claim 5, wherein a width of a portion where the first groove pattern is connected to the first surface is smaller than a width of a portion where the second groove pattern is connected to the first surface.

7. The display device of claim 5, wherein at least two widths of each of the plurality of first groove patterns are different from each other.

8. The display device of claim 1, wherein each of the plurality of groove patterns is a hole that penetrates through the substrate.

9. The display device of claim 1, wherein a storage modulus of the adhesive member is equal to or less than 105 Pa.

10. A display device comprising:
a display panel including a plurality of subpixels;
a substrate having a first surface facing the display panel and a second surface facing away from the first surface;
a plurality of groove patterns on at least one of the first surface of the substrate or the second surface of the substrate, each of the plurality of groove patterns including a first part having a surface that is at least partially flat and a second part having an outwardly convex shape; and
an adhesive member disposed on the substrate, the adhesive member filling at least a portion of the plurality of groove patterns.

11. The display device of claim 10, wherein the first surface of the substrate is closer to the display panel than the second surface of the substrate, the plurality of groove patterns are disposed on the first surface of the substrate, and the second part is connected to the first surface of the substrate.

12. The display device of claim 10, wherein an angle formed by a straight line tangent to a sidewall of the second part and the first surface increases as a location where the straight line is tangent to the sidewall of the second part is close to the first surface.

13. The display device of claim 10, wherein at least one width of widths of the second part is larger than a width of a portion where the second part is connected to the first surface.

14. The display device of claim 10, wherein the substrate includes a bending area configured to bend about an axis and a non-bending area,
wherein the plurality of groove patterns include a plurality of first groove patterns in the bending area and a plurality of second groove patterns in the non-bending area, and
wherein the plurality of second groove patterns are disposed at a lower density than the plurality of first groove patterns.

15. The display device of claim 10, wherein each of the plurality of groove patterns is a hole that penetrates through the substrate.

16. A flexible display device comprising:
a display panel including a plurality of subpixels;
a substrate having a bending area and a non-bending area;
an adhesive member disposed between the display panel and the substrate; and
a plurality of groove patterns in the bending area of the substrate, each grove pattern among the plurality of groove patterns including a first part corresponding to a bottom of the grove pattern and a second part corresponding to an opening of the grove pattern,
wherein a side of the first part has a first slope, and a side of the second part has a second slope different than the first slope, and
wherein portions of the adhesive member extend at least partially into the plurality of groove patterns.

17. The flexible display device of claim 16, wherein the portions of the adhesive member are configured to extend deeper into the plurality of groove patterns when the flexible display device is in a bent state than when the flexible display device is in a non-bent state.

18. The flexible display device of claim 16, wherein a cross section of each of the plurality of groove patterns has a bottle neck shape or a head and shoulders shape.

19. The flexible display device of claim 16, wherein each of the plurality of groove patterns is configured to more tightly grip or squeeze one the portions of the adhesive member when the flexible display device is in a bent state than when the flexible display device is in a non-bent state.

20. The flexible display device of claim 16, wherein the plurality of groove patterns include a first plurality of groove patterns disposed in the bending area of the substrate and a second plurality of groove patterns disposed in the non-bending area of the substrate, and wherein the first plurality of groove patterns are spaced closer together than the second plurality of groove patterns.
